(19) United States
(12) Patent Application Publication
(10) Pub. No.: US 2023/0058897 A1
(43) Pub. Date: Feb. 23, 2023

(54) THERMAL CONDUCTION LAYER

(71) Applicant: International Business Machines Corporation, Armonk, NY (US)

(72) Inventors: David Abraham, Croton, NY (US); Gerard McVicker, Stormville, NY (US); Sri M. Sri-Jayantha, Ossining, NY (US)

(21) Appl. No.: 17/445,248

(22) Filed: Aug. 17, 2021

(51) Int. Cl. H01L 23/367

(52) U.S. Cl. CPC H01L 23/3677

(57) ABSTRACT

Embodiments of a present invention disclose an apparatus including a silicon wafer and a through-silicon-via (TSV) filled with a thermally conductive material located in the silicon wafer, wherein the thermally conductive material has better thermal conduction properties than the silicon wafer when at cryogenic temperatures. A shunt layer connected to the thermal material in the TSV and a heat generating device located directly on top of the thermal material in the TSV and directly on top of the shunt layer, wherein the heat generated by the heat generating device is removed directly by the shunt layer and the thermal material in the TSV.

### STATEMENT REGARDING FEDERALLY FUNDED RESEARCH AND DEVELOPMENT

This invention was made with U.S. Government support. The U.S. Government has certain rights in this invention.

### BACKGROUND

The present invention relates generally to a field of heat management on microelectronic devices, and more particularly to a thermal conduction layer to remove the heat generated from a device.

Electronic devices dissipate heat which is conducted through a bulk material such as silicon to a cold reference plane. At cryogenic temperature thermal conductivity of silicon is significantly reduced which corresponds to an increase in thermal resistance through the substrate supporting the device and prevents an easy escape path for heat. Different means have been tried to reduce the heat, but at cryogenic temperatures issues arise. The thermal resistance of the substrate supporting the device at cryogenic condition is found to be the major thermal bottleneck, which in turn produces excess device temperature which can increase noise temperature of electronics and/or reduce device performance.

### BRIEF SUMMARY

Additional aspects and/or advantages will be set forth in part in the description which follows and, in part, will be apparent from the description, or may be learned by practice of the invention.

Embodiments of the present invention disclose an apparatus including a silicon wafer and a through-silicon-via (TSV) filled with a thermally conductive material located in said silicon wafer, wherein the thermally conductive material has better thermal conduction properties than the silicon wafer when at cryogenic temperatures. A shunt layer connected to the thermal material in the TSV and a heat generating device located directly on top of the thermal material in the TSV and directly on top of the shunt layer, wherein the heat generated by the heat generating device is removed directly by the shunt layer and the thermal material in the TSV.

An aspect of the invention wherein the thermal material extends above the end of the TSV, and wherein said shunt layer located on top of the silicon wafer adjacent to the thermal material that extends above the TSV.

An aspect of the invention wherein the apparatus further comprising; a trench that extends from said TSV; and a second shunt layer located within the trench.

An aspect of the invention wherein the apparatus further comprising: a third shunt layer located on top of said second shunt layer; and a second heat generating device located directly on top of the third shunt layer, wherein the heat generated by the second heat generated device is removed directly through the third shunt layer, the second shunt layer and the thermal material in the TSV.

An aspect of the invention wherein said shunt layer, the second shunt layer, the third shunt layer, and the thermal material within the TSV are comprised of the same, different, or any combination of thermal material, so long as the selected thermal materials have good thermal conductance at cryogenic temperatures.

An aspect of the invention wherein the apparatus further comprising: a trench that extends from the TSV, such that, said shunt layer is located within the trench.

An aspect of the invention wherein a top surface of said shunt layer and a top surface of the thermal material within the TSV are coplanar with the top surface of the silicon wafer.

An aspect of the invention wherein the apparatus further comprising: a first trench extending from said TSV; and a second trench extending from the TSV; wherein the length of the first trench and length of the second trench are different.

An aspect of the invention wherein said shunt layer is located within the first trench, and wherein a top surface of the shunt layer and a top surface of the thermal material within the TSV are coplanar with the top surface of the silicon wafer.

An aspect of the invention wherein the apparatus further comprising: a second shunt layer located within said second trench; wherein a top surface of the second shunt layer is coplanar with the top surface of the silicon wafer, the top surface of the thermal material within the TSV, and the top surface of the first shunt layer.

An aspect of the invention wherein the apparatus further comprising: a second heat generating device located directly on top of said second shunt layer, wherein the heat generated by the second heat generated device is removed directly through the second shunt layer and the thermal material in the TSV.

An aspect of the invention wherein said shunt layer and the second shunt layer are comprised of the same material.

An aspect of the invention wherein said shunt layer and the second shunt layer are comprised of different materials.

An aspect of the invention wherein said shunt layer, and the thermal material within the TSV are comprised of the same or different thermal material, so long as the thermal material has good thermal conductance at cryogenic temperatures.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1, is a quarter symmetry of a larger structure illustrating isotherms depicting a temperature gradient of a heat generating device in contact with the thermal TSV.

FIG. 2, illustrates a cross section of a product that has the heat generating device and a thermal escape route of a thermal TSV.

FIGS. 3A, 3B, 3C, and 3D illustrate the substrate during the formation of the via, in accordance with the embodiment of the invention.

FIGS. 4A and 4B, illustrates a cross section of a product that has a heat generating device, a thermal escape route, and a thermal shunt layer, in accordance the embodiment of the present invention.

FIGS. 5A and 5B, are a cross section of a product that has a plurality of heat generating devices, a thermal escape route, and a plurality of thermal shunt layers, in accordance with the embodiment of the present invention.

### DETAILED DESCRIPTION

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions may be omitted for clarity and conciseness.

The terms and words used in the following description and claims are not limited to the bibliographical meanings, but, are merely used to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces unless the context clearly dictates otherwise.

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the presented embodiments.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. The terms “overlying”, “atop”, “on top”, “positioned on” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” can be understood to include any integer number greater than or equal to one, i.e. one, two, three, four, etc. The terms “a plurality” can be understood to include any integer number greater than or equal to two, i.e. two, three, four, five, etc. The term “connection” can include both an indirect “connection” and a direct “connection.”

As used herein, the term “about” modifying the quantity of an ingredient, component, or reactant of the invention employed refers to variation in the numerical quantity that can occur, for example, through typical measuring and liquid handling procedures used for making concentrates or solutions. Furthermore, variation can occur from inadvertent error in measuring procedures, differences in the manufacture, source, or purity of the ingredients employed to make the compositions or carry out the methods, and the like. The terms “about” or “substantially” are intended to include the degree of error associated with measurement of the particular quantity based upon the equipment available at the time of filing application. For example, “about” can include a range of ±8% or 5%, or 2% of a given value. In one aspect, the term “about” means within 10% of the reported numerical value. In another aspect, the term “about” means within 5% of the reported numerical value. Yet, in another aspect, the term “about” means within 10, 9, 8, 7, 6, 5, 4, 3, 2, or 1% of the reported numerical value. The terms “about” or “substantially” are intended to include the degree of error associated with measurement of the particular quantity based upon the equipment available at the time of filing application.

Various processes used to form a micro-chip that will be packaged into an integrated circuit (IC) fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device.

Reference will now be made in detail to the embodiments of the present invention, examples of which are illustrated in the accompanying drawings, wherein like reference numerals refer to like elements throughout. Embodiments of the invention are generally directed to removing the thermal energy (heat) generated from a device in an efficient manner. A heat generating device is located on top of the substrate, for example, a silicon wafer, and when the unit is placed in a cryogenic system, the heat generated from the heat generation device can lead to errors within the system. A way to reduce or to remove the generated heat is to place the heat generating device on top of, or near, a thermal through-silicon-via (TSV) to dissipate the generated heat. However, hotspots can occur on the heat generating device due to poor thermal conductivity of the material forming, and underlying, the heat generating device. In those scenarios, the flow of energy from the heat generating device primarily occurs through the spot of the heat generating device in direct, or proximal, contact with the Thermal TSV. In order to reduce thermal hotpots on the heat generating device, a thermal shunt layer that is connected to the thermal TSV is added below the heat generating device. By doing so, the surface area of the heat generating device that is in direct thermal connection with a thermally conductive material is increased, thereby reducing the heat build up distal from a thermal TSV and reducing thermal hotspots on the heat generating device. Further, the shunt material is chosen to have a substantially higher thermal conductivity than the substrate, and the heat generating device, thereby enabling improved heat dissipation from the heat generating device. The shunt layer can be the same material as the thermal TSV or it can be made of different material that has good (or at least significantly better) thermal conduction properties at cryogenic temperatures, as compared to the substrate material or the heat generating device material.

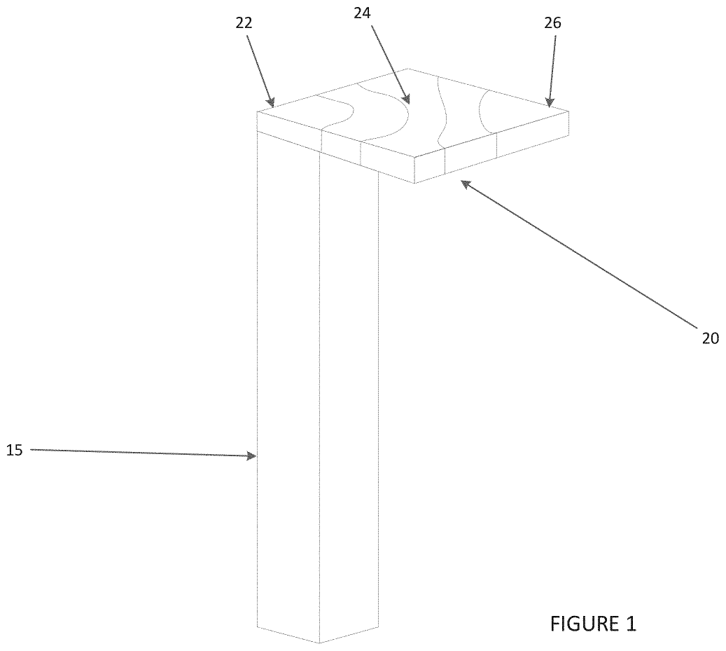

FIG. 1 is a quarter symmetry of a larger structure illustrating thermal isolines depicting energy flow of the heat generating device and a thermal escape route.

FIG. 1 illustrates an example depiction of isolines depicting a thermal gradient on heat generating device 20. FIG. 1 does not illustrate the entire heat generating device 20, but only a quarter of the device. For example, the heat generating 20 can be, for example, capacitors, resistors, transistors, inductors, sensors, antennas, amplifiers, diodes, switches, fuses, Josephson junctions, memory, pins, bump bonds, or any other electrical component or connection used in creating electrical circuits. In the illustrated example, a heat generating device 20 is located centrally on top of the thermal TSV 15, such that, the outside edges of the heat generating device 20 are about the same distance from the thermal TSV 15. The point of contact between the thermal TSV 15 and the heat generating device 20 is the lowest temperature portion 22 on the heat generating device 20. A thermal gradient 24 extends across the heat generating device 20 from the lowest temperature portion 22 located in contact with the thermal TSV 15, to highest temperature at highest temperature portion 26 located the farthest from the thermal TSV 15.

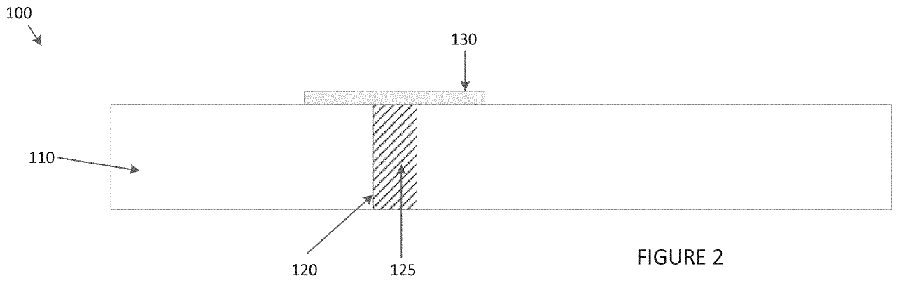

FIG. 2 is a cross sectional view of a product that has the heat generating device 130 and a thermal escape route 125.

The product 100 includes a substrate, for example, a silicon wafer 110, a via 120, a thermal material 125, and a heat generating device 130 located in contact with the thermal material 125. For example, a heat generating 130 can be, for example, capacitors, resistors, transistors, inductors, sensors, antennas, amplifiers, diodes, switches, fuses, Josephson junctions, memory, pins, bump bonds, or any other electrical component or connection used in creating electrical circuits. Only a portion of the heat generating device 130 is illustrated in the figures. The thermal TSV, as illustrated by via 120 and thermal material 125 is usually centrally located beneath the heat generating device 130. The thermal material 125 could be any type of thermal material that has a thermal conductivity better than the substrate 110 at cryogenic temperatures. The figures only show an example cross section of the layout and are not intended to be taken at scale or as illustrating the entire device. The thermal image of FIG. 1 illustrates the thermal properties of product 100, when utilizing only a thermal TSV. The material of the silicon wafer 110 that is in direct contact with the heat generating device 130 has high thermal resistance at cryogenic temperatures. As the thermal resistance within the silicon wafer 110 at cryogenic temperatures is high, the primary path of heat flow is along the plane of the heat generating device 130 to the thermal material 125 in the via 120. As shown in FIG. 1, the point of contact between the heat generating device 130 and the thermal material 125 is the lowest temperature on the heat generating device. A thermal gradient extends across the heat generating device 130 from the lowest temperature portion located in contact with the thermal material 125, to highest temperature at highest temperature portion located the farthest from the thermal material 124. A solution to reduce or remove this thermal gradient is to utilize a shunt layer 410, 415, 510, 511, 515, 516, and 520, as described below, between the heat generating device 130 and the silicon wafer 110.

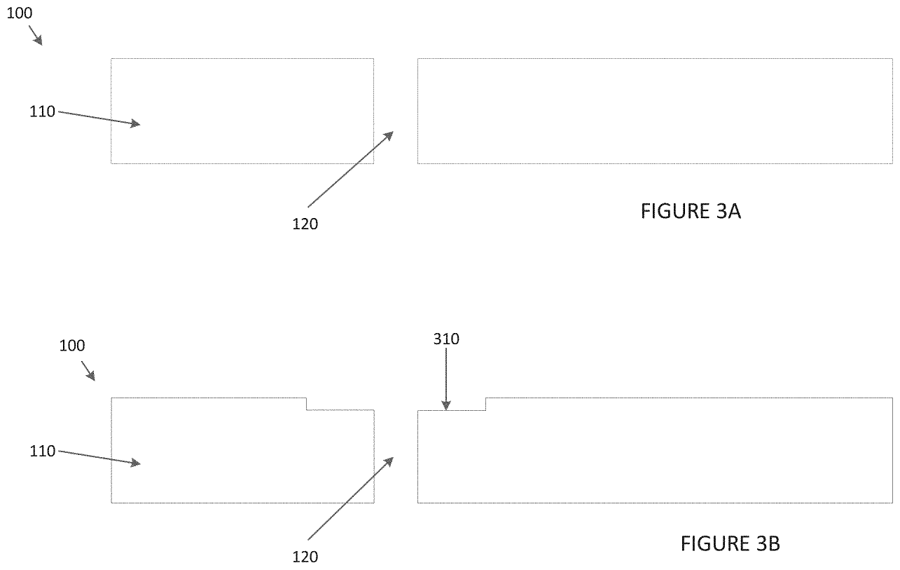

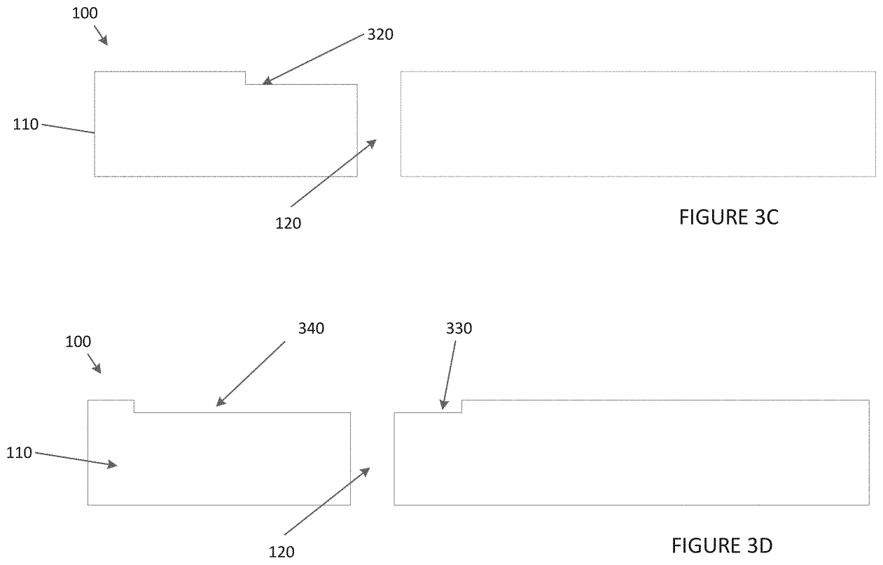

FIGS. 3A, 3B, 3C, and 3D illustrate the substrate during the formation of the via, in accordance with the embodiment of the invention.

FIG. 3A illustrates a product 100 after the via 120 is fabricated. The product 100 includes the silicon wafer 110, and the via 120. FIG. 3B illustrates a different embodiment for the fabrication of product 100.

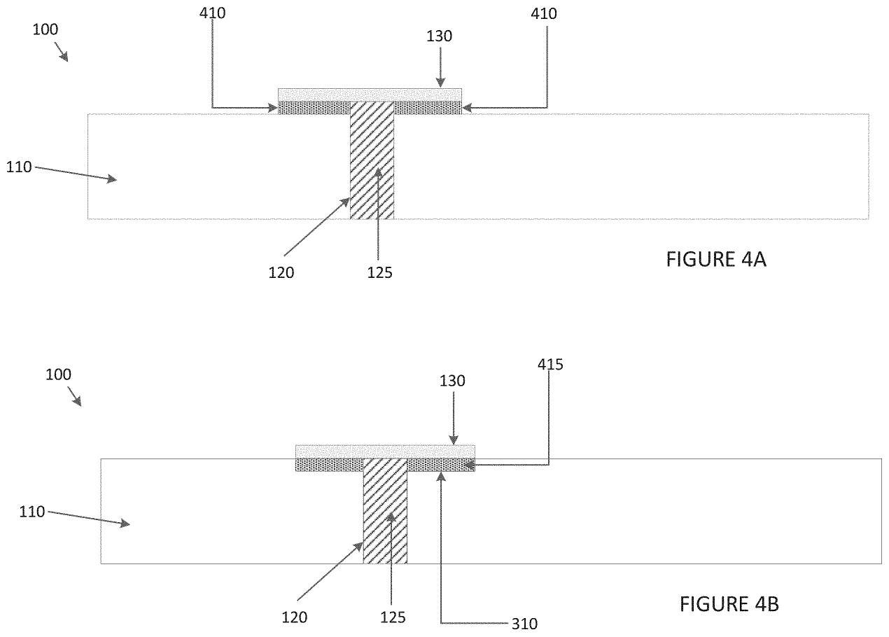

FIG. 3B further includes forming a trench 310 using a damascene process. The trench 310 allows for top surface of a shunt layer 415 to be coplanar with the top surface of the silicon wafer 110, as illustrated by FIG. 4B.

FIG. 3C is similar to FIG. 3B with the formation of a trench 320 through the damascene process. Trench 320 is longer than trench 310, this allows for the accommodation of heat generating devices that are not located directly on top of the thermal material 125 in the via 120. The depth of trench 310 and 320 is dependent upon thermal properties of the shunt material that is used plus the heat load from the heat generating device 130. FIG. 3D is similar to FIG. 3B but instead of having a single trench 310, the silicon wafer has a first trench 330 and a second trench 340. Having multiple trenches 330 and 340 allow for multiple shunt layers to be utilized. The length of the trenches 330 and 340 are not the necessarily the same.

FIGS. 4A and 4B, illustrates a cross section of a product that has a heat generating device, a thermal escape route, and a thermal shunt layer, in accordance the embodiment of the present invention.

FIG. 4A illustrate the product 100 utilizing only the via 120, as illustrated by FIG. 3A. At low temperatures, for example, temperatures in a cryogenic range, the silicon wafer 110 has poor thermal conduction properties. The via 120 is filled with a thermal material 125, such that, the thermal material 125 extends higher than the top surface of silicon wafer 110. At low temperatures, for example, temperatures in the cryogenic range, the silicon wafer 110 has poor thermal conduction properties. The thermal conduction properties of the thermal material 125 needs to be better than thermal conduction properties of the silicon wafer 110 when at cryogenic temperatures, for example, the thermal material 125 can be copper, tungsten, or any other suitable material. Only a portion of the heat generating device 130 is illustrated in the figures. The thermal TSV, as illustrated by via 120 and thermal material 125 may be centrally located beneath the heat generating device 130. The figures only show an exemplary cross section of the layout and are not intended to be at scale or as illustrating the entire device. A shunt layer 410 is formed adjacent to the thermal material 125 that extends beyond the top surface of silicon wafer 110. The shunt layer 410 can be comprised of the same material as the thermal material 125 or it can be a different material that has better thermal conduction properties than the silicon wafer 110at cryogenic temperatures. The heat generating device 130 is located top of the thermal material 125 and the shunt layer 410. This allows for the heat generated by the heat generating device 130 to be removed through the combined surface area of the shunt layer 410 and the thermal material 125, thus removing the thermal bottleneck. The shunt layer 410 extends across the entire bottom surface of the heat generating device 130 that is not in contact with the thermal material 125, this allows for the heat to be removed along the entire bottom surface of heat generating devices 130.

FIG. 4B illustrate the product 100 utilizing the via 120 and trench 310, as illustrated by FIG. 3B. At low temperatures such as, for example, temperatures in a cryogenic range, the silicon wafer 110 has poor thermal conduction properties. The via 120 is filled with a thermal material 125, such that, the top surface of the thermal material 125 is coplanar with the top surface of silicon wafer 110. At low temperatures, for example, temperatures in the cryogenic range, the silicon wafer 110 has poor thermal conduction properties. The thermal conduction properties of the thermal material 125 needs to be better than thermal conduction properties of the silicon wafer 110 when at cryogenic temperatures, for example, the thermal material 125 can be copper, tungsten, or any other suitable material. Only a portion of the heat generating device 130 is illustrated in the figures. The thermal TSV, as illustrated by via 120 and thermal material 125 is usually centrally located beneath the heat generating device 130. The figures only show an exemplary cross section of the layout and are not intended to taken to be scale or as illustrating the entire device. A shunt layer 415 is formed in trench 310 adjacent to the thermal material 125 and the top surface of the shunt layer 415 is coplanar with the top surface of the silicon wafer 110. The shunt layer 415 can be comprised of the same material as the thermal material 125 or it can be a different material that has better thermal conduction properties than the silicon wafer 110at cryogenic temperatures. The heat generating device 130 sits on top of the thermal material 125 and the shunt layer 415. This allows for the heat generated by the heat generating device 130 to be removed through the combined surface are of the shunt layer 415 and the thermal material 125, thus removing the thermal bottleneck. The shunt layer 415 extends across the entire bottom surface of the heat generating device 130 that is not in contact with the thermal material 125, this allows for the heat to be removed along the entire bottom surface of heat generating devices 130. By utilizing trench 310, it allows for the top surface of the thermal material 125 and the top surface of the shunt layer 415 to be coplanar with the top surface of the silicon wafer 110.

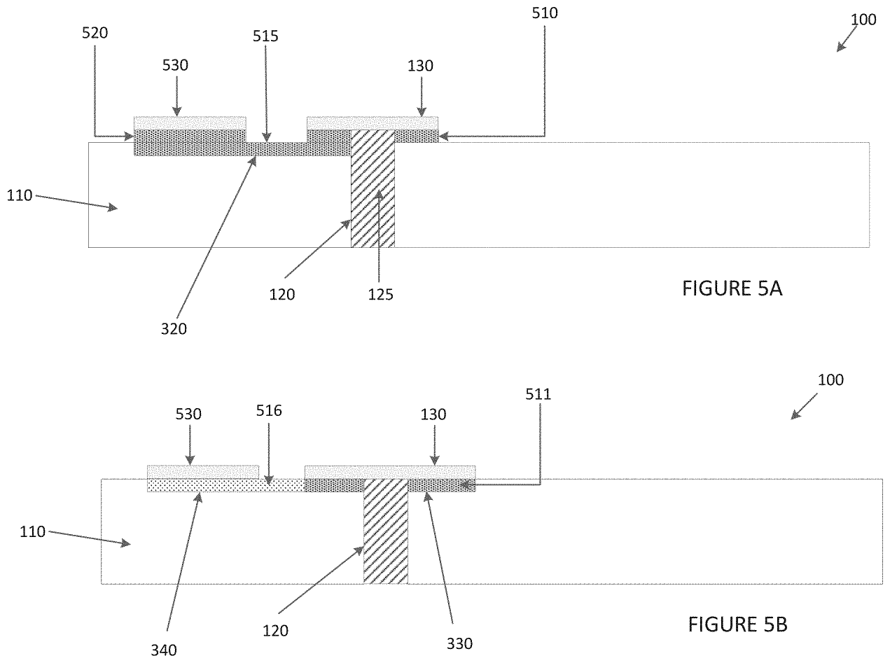

FIGS. 5A and 5B are a cross section of a product that has a plurality of heat generating devices, a thermal escape route, and a plurality of thermal shunt layers, in accordance with the embodiment of the present invention.

FIG. 5A illustrate the product 100 utilizing the via 120 and trench 320, as illustrated by FIG. 3C. At low temperatures, for example, temperatures in a cryogenic range, the silicon wafer 110 has poor thermal conduction properties. The via 120 is filled with a thermal material 125, such that, the thermal material 125 extends higher than the top surface of silicon wafer 110. At low temperatures, for example, temperatures in the cryogenic range, the silicon wafer 110 has poor thermal conduction properties. The thermal conduction properties of the thermal material 125 needs to be better than thermal conduction properties of the silicon wafer 110 when at cryogenic temperatures, for example, the thermal material 125 can be copper, tungsten, or any other suitable material. Only a portion of the heat generating device 130 is illustrated in the figures. The thermal TSV, as illustrated by via 120 and thermal material 125 is usually centrally located beneath the heat generating device 130. The figures only show an exemplary cross section of the layout and are not intended to taken on scale or as illustrating the entire device. A first shunt layer 510 is formed adjacent to the thermal material 125 that extends beyond the top surface of silicon wafer 110. The first shunt layer 510 can be comprised of the same material as the thermal material 125 or it can be a different material that has better thermal conduction properties than the silicon wafer 110at cryogenic temperatures. The heat generating device 130 sits on top of the thermal material 125 and the shunt layer 510. This allows for the heat generated by the first heat generating device 130 to be removed through the combined surface area of the shunt layer 510 and the thermal material 125, thus removing the thermal bottleneck. The shunt layer 510 extends across the entire bottom surface of the first heat generating device 130 that is not in contact with the thermal material 125, this allows for the heat to be removed along the entire bottom of the first heat generating devices 130.

A second shunt layer 515 is formed in trench 320 adjacent to the thermal material 125 and the top surface of a second shunt layer 515 is coplanar with the top surface of the silicon wafer 110. A third shunt layer 520 is formed on top of second shunt layer 515. A second heat generating device 530 is located on top of the third shunt layer 520. The second shunt layer 515 and the third shunt layer 520 can be comprised of the same material as the thermal material 125 or it can be a different material that has better thermal conduction properties than the silicon wafer 110 at cryogenic temperatures. The third shunt layer 520 extends across the entire bottom surface of the second heat generating device 530, this allows for the heat to be removed along the entire bottom surface of the second heat generating devices 530. By utilizing trench 320, the second shunt layer 515 and the third shut layer 520 allow for multiple heat generating devices 130 and 530 to be in thermal connection with the thermal material 125. The above description is an example only, one of ordinary skill in the art would realize that above description is not limited to only connecting two heat generating devices to one thermal TSV, as a plurality of heat generating devices may be connected to a single TSV using a shunt of the current system.

FIG. 5B illustrate a product 100 utilizing the via 120, a first trench 330 and a second trench 340, as illustrated by FIG. 3D.

At low temperatures, for example, temperatures in a cryogenic range, the silicon wafer 110 has poor thermal conduction properties. The via 120 is filled with a thermal material 125, such that, the top surface of the thermal material 125 is coplanar with the top surface of silicon wafer 110. At low temperatures, for example, temperatures in the cryogenic range, the silicon wafer 110 has poor thermal conduction properties. The thermal conduction properties of the thermal material 125 needs to be better than thermal conduction properties of the silicon wafer 110 when at cryogenic temperatures, for example, the thermal material 125 can be copper, tungsten, or any other suitable material. A shunt layer 511 is formed in the first trench 330 adjacent to the thermal material 125 and the top surface of the shunt layer 511 is coplanar with the top surface of the silicon wafer 110. The shunt layer 511 can be comprised of the same material as the thermal material 125 or it can be a different material that has better thermal conduction properties than the silicon wafer 110 at cryogenic temperatures. The heat generating device 130 sits on top of the thermal material 125 and the shunt layer 511. This allows for the heat generated by the heat generating device 130 to be removed through the combined surface area of the shunt layer 511 and the thermal material, thus removing the thermal bottleneck. The shunt layer 511 extends across the entire bottom surface of the heat generating device 130 that is not in contact with the thermal material 125, this allows for the heat to be removed along the entire bottom surface of heat generating devices 130.

A second shunt layer 516 is formed in the second trench 340 adjacent to the thermal material 125 and the top surface of the second shunt layer 516 is coplanar with the top surface of the silicon wafer 110. The second trench 350 has the same depth as the first trench 340. The depth of trench 340 is dependent thermal properties of the shunt material that is used plus the heat load from the heat generating device 530. The same thermal material can be utilized for the first shunt layer 511 and the second shunt layer 516 as long as the thermal material has better thermal conduction properties than the silicon wafer 110 at cryogenic temperatures and can conduct the heat generated from the devices 130 and 530. However, the thermal material utilized in the first shunt layer 511 and the second shunt layer can be different, as long as each material can conduct the heat generated from each device 130 and 530, respectively, to the thermal material 125 in the via 120.

A second heat generating device 530 is located on top of the second shunt layer 516. The second shunt layer 516 extends across an entire bottom surface of the second heat generating device 530. This may allow for the heat to be removed along the entire bottom surface of the second heat generating devices 530. By utilizing multiple trenches 330 and 340, and multiple shunt layers 511, and 516, the thermal material 125 can be in a thermal connection to multiple heat generating devices 130, and 530. The first trench 330 and the second trench 340 are not necessarily same length. The second trench 340 can be longer to compensate for second heat generating device 530 being place at a different distance from the thermal TSV 120, 125. The above description is an example only, one of ordinary skill in the art would realize that above description is not limited to only connecting two heat generating devices to one thermal TSV, as a plurality of heat generating devices may be connected to a single TSV using a shunt of the current system.

While the invention has been shown and described with reference to certain exemplary embodiments thereof, it will be understood by those skilled in the art that various changes in form and details may be made therein without departing from the spirit and scope of the present invention as defined by the appended claims and their equivalents.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the one or more embodiment, the practical application or technical improvement over technologies found in the marketplace, or to enable others of ordinary skill in the art to understand the embodiments disclosed herein.

What is claimed is:

1. An apparatus comprising:
a silicon wafer;
a through-silicon-via (TSV) filled with a thermally conductive material located in said silicon wafer, wherein the thermally conductive material has better thermal conduction properties than the silicon wafer when at cryogenic temperatures;
a shunt layer connected to the thermal material in the TSV; and
a heat generating device located directly on top of the thermal material in the TSV and directly on top of the shunt layer, wherein the heat generated by the heat generating device is removed directly by the shunt layer and the thermal material in the TSV.

2. The apparatus of claim 1, wherein said thermal material extends above the end of the TSV, and wherein the shunt layer located on top of the silicon wafer adjacent to the thermal material that extends above the TSV.

3. The apparatus of claim 2, further comprising;
a trench that extends from said TSV; and
a second shunt layer located within the trench.

4. The apparatus of claim 3, further comprising:
a third shunt layer located on top of said second shunt layer; and
a second heat generating device located directly on top of the third shunt layer, wherein the heat generated by the second heat generated device is removed directly through the third shunt layer, the second shunt layer and the thermal material in the TSV.

5. The apparatus of claim 4, wherein said shunt layer, the second shunt layer, the third shunt layer, and the thermal material within the TSV are comprised of the same, different, or any combination of thermal material, so long as the selected thermal materials have good thermal conductance at cryogenic temperatures.

6. The apparatus of claim 1, further comprising:
a trench that extends from said TSV, such that, the shunt layer is located within the trench.

7. The apparatus of claim 6, wherein a top surface of said shunt layer and a top surface of the thermal material within the TSV are coplanar with the top surface of the silicon wafer.

8. The apparatus of claim 1, further comprising:
a first trench extending from said TSV; and
a second trench extending from the TSV;
wherein the length of the first trench and length of the second trench are different.

9. The apparatus of claim 8, wherein said shunt layer is located within the first trench, and wherein a top surface of the shunt layer and a top surface of the thermal material within the TSV are coplanar with the top surface of the silicon wafer.

10. The apparatus of claim 9, further comprising:
a second shunt layer located within said second trench;
wherein a top surface of the second shunt layer is coplanar with the top surface of the silicon wafer, the top surface of the thermal material within the TSV, and the top surface of the first shunt layer.

11. The apparatus of claim 10, further comprising:
a second heat generating device located directly on top of said second shunt layer, wherein the heat generated by the second heat generated device is removed directly through the second shunt layer and the thermal material in the TSV.

12. The apparatus of claim 10, wherein said shunt layer and the second shunt layer are comprised of the same material.

13. The apparatus of claim 10, wherein said shunt layer and the second shunt layer are comprised of different materials.

14. The apparatus of claim 1, wherein said shunt layer, and the thermal material within the TSV are comprised of the same or different thermal material, so long as the thermal material has good thermal conductance at cryogenic temperatures.
